(19) United States
(12) Patent Application Publication
(10) Pub. No.: US 2006/0132055 A1
(43) Pub. Date: Jun. 22, 2006

(54) Organic light emitting display and method of fabricating the same

(76) Inventor: Won Kyu Kwak, Seongnam (KR)

Correspondence Address: H.C. PARK & ASSOCIATES, PLC, 8500 LEESBURG PIKE, SUITE 7500, VIENNA, VA, 22182, US

(21) Appl. No.: 11/295,461

(22) Filed: Dec. 7, 2005

(30) Foreign Application Priority Data
Dec. 9, 2004 (KR) 10-2004-0103816

(51) Int. Cl. G09G 3/10

(52) U.S. Cl. 315/169.3

(57) ABSTRACT

An organic light emitting display includes pixel power source lines electrically connected with each other by metal lines to make the voltage levels of the pixel power sources uniform and reduce the voltage drops of the pixel driving power sources.

### CROSS REFERENCE TO RELATED APPLICATIONS

This application claims priority to and the benefit of Korean Patent Application No. 10-2004-103816, filed on Dec. 9, 2004, which is hereby incorporated by reference for all purposes as if fully set forth herein.

### BACKGROUND

1. Field of the Invention

The present invention relates to an organic light emitting display and a method of fabricating the same, and more particularly to an organic light emitting display in which power source lines are electrically connected with intersecting metal lines to form a grid to minimize the voltage drop of the power sources and a method of fabricating the same.

2. Discussion of Related Art

Organic light emitting displays are spontaneous emission devices that emit light by the recombination of electrons and holes. Organic light emitting displays may be classified as passive organic light emitting displays or active organic light emitting displays depending on the driving method used.

FIG. 1 illustrates the structure of a conventional organic light emitting display. Referring to FIG. 1, the organic light emitting display includes an image display unit 10 for displaying images, a data driver 20 for transmitting data signals, and a scan driver 30 for transmitting scan signals.

The image display unit 10 includes a plurality of pixels 11 that include organic light emitting diodes (OLED) and pixel circuits. The image display unit 10 also includes a plurality of scan lines S1, S2, . . . , Sn−1, and Sn arranged in a row direction, a plurality of data lines D1, D2, . . . , Dm−1, and Dm arranged in a column direction, a plurality of pixel power source lines Vdd for supplying pixel power sources, and a first power source line 12 for transmitting power to the pixel power source lines Vdd.

The scan signals transmitted from the scan lines S1, S2, . . . , Sn−1, and Sn and data signals transmitted from the data lines D1, D2, . . . , Dm−1, and Dm are transmitted to the pixel circuits. The pixel circuits generate currents corresponding to the data signals and transmit the currents to the OLEDs.

The data driver 20 is connected with the data lines D1, D2, . . . , Dm−1, and Dm to transmit the data signals to the image display unit 10.

The scan driver 30 is arranged on the side of the image display unit 10 and is connected with the scan lines S1, S2, . . . , Sn−1, and Sn to transmit the scan signals to the image display unit 10. The data signals are transmitted to the pixels 11 that receive the scan signals.

In a conventional organic light emitting display, the magnitude of the voltage drop (IR Drop) of the pixel driving voltages are different from each other due to non-uniformity in line resistances caused by the lengths of the pixel power source lines Vdd commonly connected to the first power source line 12. The magnitude of the voltage drop of the pixel power source lines Vdd increases as the distance of the pixel power source lines Vdd from the first power source line 12 increases.

Therefore, in a conventional organic light emitting display, the amount of current from the data signal varies with the position of each pixel 11, and causes the emission brightness to become non-uniform.

### SUMMARY OF THE INVENTION

This invention provides a light emitting display that includes pixel power source lines electrically connected with intersecting metal lines through contact holes. The pixel power source lines and the intersecting metal lines are arranged as a mesh to make the voltage levels of the pixel power sources uniform and reduce the voltage drops of the pixel driving power sources.

This invention also provides a light emitting display in which metal lines that transmit power are narrower where the metal lines intersect data lines than the width of the metal lines where the metal lines do not intersect the data lines to reduce the capacity of the parasitic caps formed between the metal lines and the data lines.

Additional features of the invention will be set forth in the description which follows, and in part will be apparent from the description, or may be learned by practice of the invention.

The present invention discloses an organic light emitting display, including a plurality of pixels, a plurality of scan lines transmitting scan signals to the plurality of pixels, a plurality of data lines transmitting data signals to the plurality of pixels, and a plurality of pixel power source lines transmitting power to the plurality of pixels, wherein the plurality of pixels comprise a plurality of metal lines that intersect the plurality of pixel power source lines, and wherein the plurality of metal lines are electrically connected with the plurality of pixel power source lines.

The present invention also discloses a method of fabricating an organic light emitting display, including forming channel regions of transistors and first electrodes of capacitors on a substrate, wherein the channel regions of transistors and first electrodes of capacitors comprise polysilicon, forming a first insulating layer on the channel regions of the transistors and the first electrodes of the capacitors, forming scan lines and second electrodes of the capacitors on the first insulating layer, wherein adjacent second electrodes of the capacitors are electrically connected with each other and wherein the second electrodes of the capacitors are arranged in a line substantially parallel to the scan lines, forming a second insulating layer on the scan lines and the second electrodes of the capacitors, forming contact holes in the second insulating layer so that the contact holes expose the second electrodes of the capacitors, and forming data lines and pixel power source lines on the second insulating layer, wherein the pixel power source lines are electrically connected with the second electrodes of the capacitors through the contact holes.

The present invention also discloses a method of fabricating an organic light emitting display, including forming a channel region of a first transistor, a channel region of a second transistor, a channel region of a third transistor, a channel region of a fourth transistor, a channel region of a fifth transistor, a first electrode of a first capacitor, and a first electrode of a second capacitor on a substrate, wherein the channel region of the first transistor, the channel region of the second transistor, the channel region of the third transistor, the channel region of the fourth transistor, the channel region of the fifth transistor, the first electrode of the first capacitor, and the first electrode of the second capacitor comprise polysilicon, forming a first insulating layer on the channel region of the first transistor, the channel region of the second transistor, the channel region of the third transistor, the channel region of the fourth transistor, the channel region of the fifth transistor, the first electrode of the first capacitor, and the first electrode of the second capacitor, forming scan lines, emission control lines, a second electrode of the first capacitor, and a second electrode of the second capacitor on the first insulating layer, wherein adjacent second electrodes of the capacitors are electrically connected with each other and wherein the second electrodes of the capacitors are arranged in a line substantially parallel to the scan lines, forming a second insulating layer on the scan lines, the emission control lines, the second electrode of the first capacitor, and the second electrode of the second capacitor, forming contact holes in the second insulating layer so that the contact holes expose the second electrodes of the first capacitors; and forming data lines, pixel power source lines, and the first electrodes of third capacitors on the second insulating layer, wherein the pixel power source lines are electrically connected with the second electrodes of the first capacitors through the contact holes.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 illustrates the structure of a conventional organic light emitting display.

FIG. 2 illustrates the structure of an organic light emitting display according to an exemplary embodiment of the present invention.

FIG. 3 is a circuit diagram illustrating an exemplary embodiment of the pixel that may be used in the organic light emitting display of FIG. 2.

FIG. 4A, FIG. 4B, FIG. 4C, and FIG. 4D are layout diagrams illustrating the layouts of the image display unit for which the pixel of FIG. 3 may be used.

FIG. 5 illustrates the structure of an organic light emitting display according to an exemplary embodiment of the present invention.

FIG. 6 illustrates a first exemplary embodiment of the pixel that may be used in the organic light emitting display of FIG. 5.

FIG. 7 is a timing diagram illustrating the operation of the pixel of FIG. 6.

FIG. 8 illustrates a second exemplary embodiment of the pixel that may be used in the organic light emitting display of FIG. 5.

FIG. 9 is a timing diagram illustrating the operation of the pixel of FIG. 8.

FIG. 10A, FIG. 10B, FIG. 10C, and FIG. 10D are layout diagrams illustrating the layouts of the image display unit for which the pixel of FIG. 6 may be used.

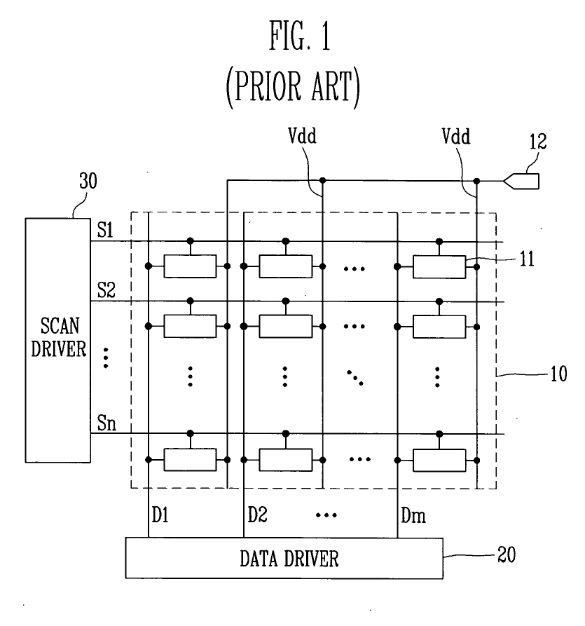

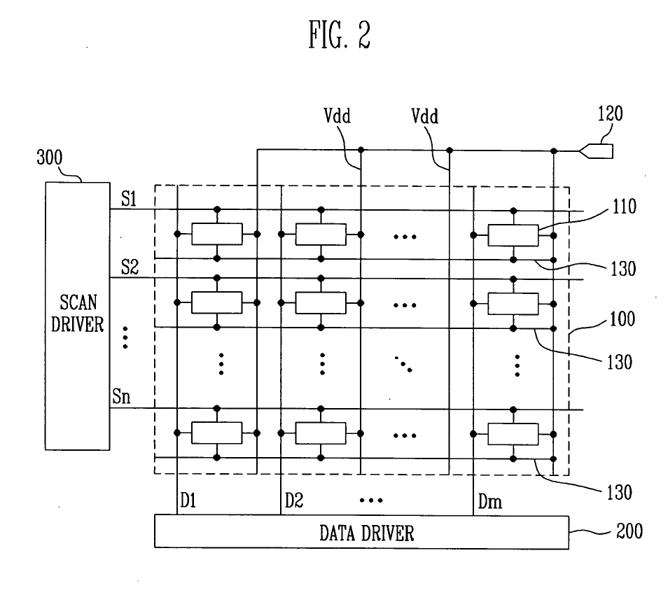

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element such as a layer, film, region or substrate is referred to as being “on” another element, it can be directly on the other element or intervening elements may also be present. In contrast, when an element is referred to as being “directly on” another element, there are no intervening elements present.

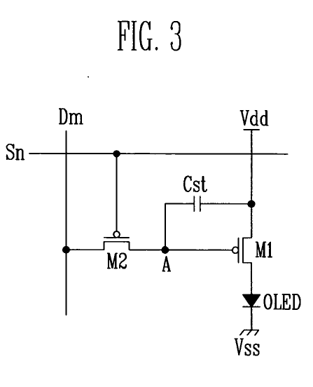

FIG. 2 illustrates an organic light emitting display according to an exemplary embodiment of the present invention. Referring to FIG. 2, the organic light emitting display may include an image display unit 100 for displaying images, a data driver 200 for transmitting data signals, and a scan driver 300 for transmitting scan signals.

The image display unit 100 may include a plurality of pixels 110 that include organic light emitting diodes (OLED) and pixel circuits. The image display unit 100 may also include a plurality of scan lines S1, S2, . . . , Sn−1, and Sn arranged in a row direction, a plurality of data lines D1, D2, . . . , Dm−1, and Dm arranged in a column direction, a plurality of pixel power source lines Vdd for supplying pixel power sources, a first power source line 120 for transmitting power to the pixel power source lines Vdd, and metal lines 130 arranged in a horizontal direction to electrically connect the pixel power source lines Vdd with each other. The metal lines 130 are connected with the pixels to transmit power to the pixels. The pixel power source lines Vdd are electrically connected with each other by the metal lines 130 so that the voltage applied to every pixel power source line Vdd is uniform.

The scan signals transmitted from the scan lines S1, S2, . . . , Sn−1, and Sn and the data signals transmitted from the data lines D1, D2, . . . , Dm−1, and Dm are transmitted to the pixel circuits. The pixel circuits generate currents corresponding to the data signals to transmit the currents to the OLEDs.

The data driver 200 is connected with the data lines D1, D2, . . . , Dm−1, and Dm to transmit the data signals to the image display unit 100.

The scan driver 300 may be arranged on the side of the image display unit 100 and is connected with the plurality of scan lines S1, S2, . . . , Sn−1, and Sn to transmit the scan signals to the image display unit 100. The data signals are transmitted to the pixels 110 that receive the scan signals.

FIG. 3 illustrates a first exemplary embodiment of the pixel that may be used in the organic light emitting display of FIG. 2. Referring to FIG. 3, the pixel may include a pixel circuit and an OLED. The pixel circuit may include a first transistor M1, a second transistor M2, a third transistor M3, and a capacitor Cst. The first transistor M1, the second transistor M2, and the third transistor M3 each include a source, a drain, and a gate. The capacitor Cst includes a first electrode and a second electrode.

The source of the first transistor M1 is connected to the pixel power source line Vdd, the drain of the first transistor M1 is connected to the source of a third transistor M3, and the gate of the first transistor M1 is connected to a first node A. The first node A is connected to the drain of the second transistor M2. The first transistor M1 supplies current corresponding to a data signal to the OLED.

The source of the second transistor M2 is connected to the data line Dm, the drain of the second transistor M2 is connected to the first node A, and the gate of the second transistor M2 is connected to the first scan line Sn. The second transistor M2 transmits a data signal to the first node A in accordance with the scan signal applied to the second transistor's M2 gate.

The first electrode of the capacitor Cst is connected with the power source supply line Vdd. The second electrode of the capacitor is connected with the first node A. The capacitor Cst charges in accordance with a data signal and uses the charge to apply a signal to the gate of the first transistor M1 for one frame so that the first transistor M1 is operated for one frame.

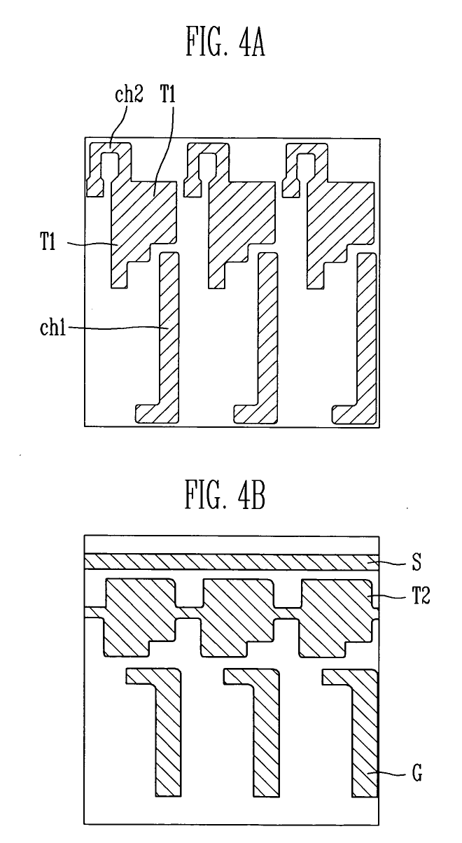

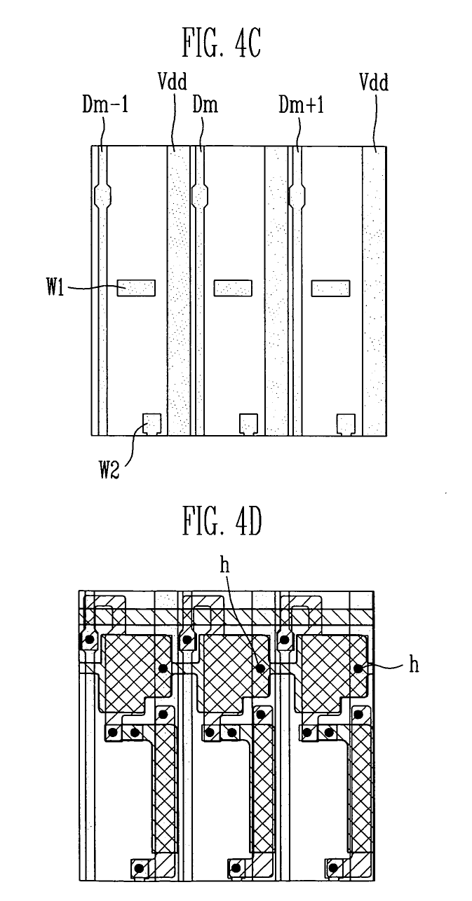

FIG. 4A, FIG. 4B, FIG. 4C, and FIG. 4D are layout diagrams illustrating the layouts of the image display unit 100 for which the pixel of FIG. 3 may be used. Referring to FIG. 4A, FIG. 4B, FIG. 4C, and FIG. 4D, polysilicon is formed on a substrate as illustrated in FIG. 4A to form the channel regions ch1 of the first transistors M1, the channel regions ch2 of the second transistors M2, and the first electrodes T1 of the capacitors Cst on the substrate. The channel regions ch2 of the second transistors M2 and the first electrodes T1 of the capacitors Cst are connected with each other. Doped polysilicon or intrinsic polysilicon may be used as the polysilicon.

As illustrated in FIG. 4B, a first metal layer is used to form a scan line S on the channel regions ch2 of the second transistors M2 in a horizontal direction, second electrodes T2 of the capacitors Cst that face the first electrodes T1 of the capacitors Cst, and gate electrodes G that overlap the channel regions ch1 of the first transistors M1. The second electrodes T2 of the capacitors Cst adjacent to each other in a horizontal direction are connected with each other.

As illustrated in FIG. 4C, a second metal layer is used to form the data lines Dm and the pixel power source lines Vdd, which are separated from each other by a predetermined distance in a horizontal direction, first wiring lines W1 that connect the first electrodes T1 of the capacitors Cst with the gate electrodes G, and second wiring lines W2 that connect the channel regions ch1 of the first transistors M1 with the anode electrodes of the OLEDs. The channel regions ch2 of the second transistors M2 are electrically connected with the data lines Dm. The channel regions ch1 of the first transistor M1 are electrically connected with the pixel power source lines Vdd. The second electrodes T2 of the capacitors Cst are electrically connected with the pixel power source lines Vdd through contact holes h. Insulating layers are deposited between the polysilicon layer, the first metal layer, and the second metal layer. FIG. 4D shows the completed image display unit.

Referring to FIG. 4D, the sites where the data lines Dm are connected with the channel regions ch2 of the second transistors M2 become the sources of the second transistors M2. The sites where the first electrodes T1 of the capacitors are connected with the gate electrodes G by the first wiring lines W1 become the drains of the second transistors M2. The sites where the channel regions ch2 of the second transistors M2 and the scan lines overlap each other become the gates of the second transistors M2. The sites where the channel regions ch2 of the second transistors M2 are connected with the pixel power source lines Vdd become the sources of the second transistors M2. The sites where the anode electrodes of the OLEDs are connected with the channel regions ch1 of the first transistors M1 by the second wiring lines W2 become the drains of the first transistors M1. The sites where the channel regions ch1 of the first transistors M1 and the gate electrodes G overlap each other become the gates of the first transistors M1. The sites where the channel regions ch1 of the first transistors M1 and the gate electrodes G overlap each other become the second electrodes T2 of the capacitors Cst.

The pixel power source lines Vdd and the second electrodes T2 of the capacitors Cst are electrically connected with each other so that the power transmitted through the pixel power source lines Vdd is transmitted to the second electrodes T2 of the capacitors Cst. The second electrodes T2 of the capacitors Cst adjacent to each other are connected with each other. Therefore, the second electrodes T2 of the capacitors Cst and the pixel power source lines Vdd have the same voltage level.

The pixel power source lines Vdd and the second electrodes T2 of the capacitors Cst become power source lines that supply the driving power sources to the pixels 110. The pixel power source lines Vdd and the second electrodes T2 of the capacitors Cst thus form a grid. The widths of the pixel power source lines, the second electrodes T2 of the capacitors Cst, and the data source lines where the pixel power source lines and the second electrodes T2 of the capacitors Cst intersect the data lines are narrow to reduce the parasitic caps formed at the intersection of the pixel power source lines and the second electrodes T2 of the capacitors Cst with the data lines.

When a large amount of current is supplied to one pixel so that a voltage drop is generated in the pixel power source line Vdd directly connected with a pixel 110, the voltage drop is generated in all of the pixel power source lines Vdd because all of the pixel power source lines Vdd are connected with each other by the second electrodes T2 of the capacitors Cst. It is therefore possible to reduce the voltage drops of the pixel power source lines Vdd.

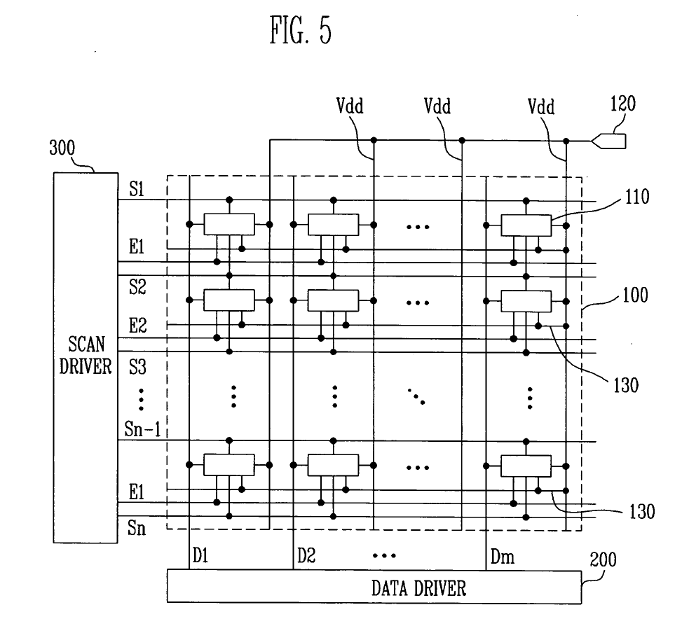

FIG. 5 illustrates the structure of a light emitting display according to an exemplary embodiment of the present invention. Referring to FIG. 5, the light emitting display may include an image display unit 100 for displaying images, a data driver 200 for transmitting data signals, and a scan driver 300 for transmitting scan signals.

The image display unit 100 may include a plurality of pixels 110 that include OLEDs and pixel circuits. The image display unit 100 may also include a plurality of scan lines S1, S2, . . . , Sn−1, and Sn arranged in a row direction, a plurality of emission control lines E1, E2, . . . , En−1, and En arranged in a row direction, a plurality of data lines D1, D2, . . . , Dm−1, and Dm arranged in a column direction, a plurality of pixel power source lines Vdd for supplying pixel power sources, a first power source line 120 for transmitting pixel power sources to the pixel power source lines Vdd, and metal lines 130 arranged in a horizontal direction to electrically connect the pixel power source lines Vdd with each other. The metal lines are connected with the pixels to transmit power sources to the pixels. The plurality of pixel power source lines Vdd are electrically connected with each other by the metal lines 130 so that the voltages applied to the entire pixel power source lines Vdd are uniform.

In the image display unit 100, the scan signals transmitted from the scan lines S1, S2, . . . , Sn−1, and Sn and the data signals transmitted from the data lines D1, D2, . . . , Dm−1, and Dm are transmitted to the pixel circuits. The pixel circuits generate currents corresponding to the data signals to transmit the currents to the OLEDs.

The data driver 200 is connected with the data lines D1, D2, . . . , Dm−1, and Dm to transmit the data signals to the image display unit 100.

The scan driver 300 may be arranged on the side of the image display unit 100 and is connected with the scan lines S1, S2, . . . , Sn−1, and Sn and emission control lines E1, E2, . . . , En−1, and En to transmit the scan signals and the emission control signals to the image display unit 100. The data signals are transmitted to the pixels 10 that receive the scan signals and the pixels emit light by the emission control signals.

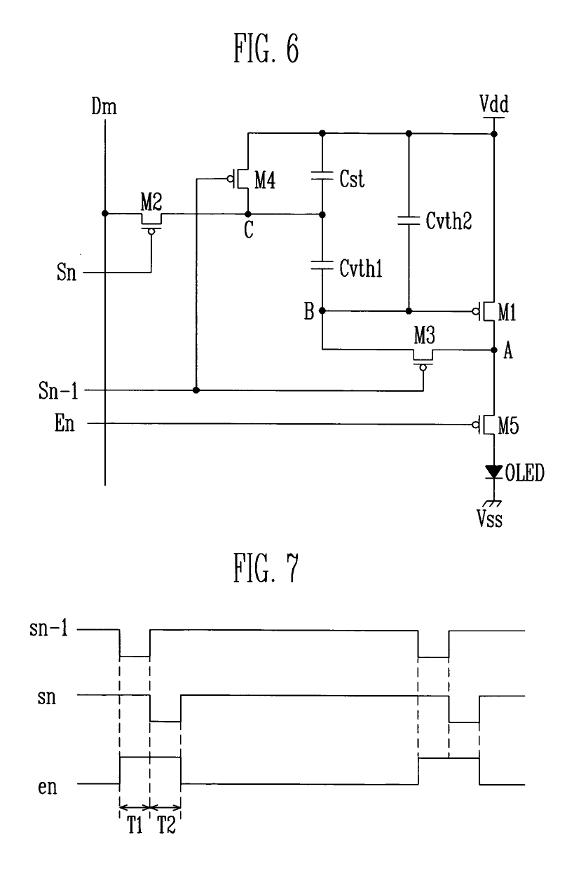

FIG. 6 is a circuit diagram illustrating a first exemplary embodiment of the pixel that may be used in the light emitting display of FIG. 5. Referring to FIG. 6, the pixel includes an OLED and a pixel circuit 110. The pixel circuit 110 includes a first transistor M1, a second transistor M2, a third transistor M3, a fourth transistor M4, a fifth transistor M5, a first capacitor Cst, a second capacitor Cvth1, and a third capacitor Cvth2.

Each of the transistors includes a source, a drain, and a gate. The transistors may be PMOS transistors. Each source and drain of the transistors may be referred to as a first electrode and a second electrode, respectively, because the sources and drains of the transistors have no physical difference. Each capacitor includes a first electrode and a second electrode.

The source of the first transistor M1 is connected with the pixel power source line Vdd, the drain of the first transistor M1 is connected with a first node A, and the gate of the first transistor M1 is connected with a second node B so that the first transistor M1 determines the amount of current that flows from the first transistor M1 source to the first transistor M1 drain in accordance with the voltage applied to the first transistor M1 gate.

The source of the second transistor M2 is connected with the data line Dm, the drain of the second transistor M2 is connected with a third node C, and the gate of the second transistor M2 is connected with the first scan line Sn so that the second transistor M2 performs on and off operations according to the first scan signal sn transmitted through the first scan line Sn to selectively transmit the data signal transmitted through the data line Dm to the third node C.

The source of the third transistor M3 is connected with the first node A, the drain of the third transistor M3 is connected with the second node B, and the gate of the third transistor M3 is connected with the second scan line Sn−1 so that the third transistor M3 performs on and off operations according to the second scan signal sn−1 transmitted through the second scan line Sn−1 to make the potential of the first node A equal to the potential of the second node B. Therefore, electric current flows through the first transistor M1 so that the first transistor M1 serves as a diode.

The source of the fourth transistor M4 is connected with the pixel power source line Vdd, the drain of the fourth transistor M4 is connected with the third node C, and the gate of the fourth transistor M4 is connected with the second scan line Sn−1 so that the fourth transistor M4 selectively transmits the pixel power source to the third node C in accordance with the scan signal sn−1.

The source of the fifth transistor M5 is connected with the first node A, the drain of the fifth transistor M5 is connected with the OLED, and the gate of the fifth transistor M5 is connected with the emission control line En so that the fifth transistor M5 performs on and off operations by the emission control signal en transmitted through the emission control line En to allow current to flow from the first node A to the OLED, which causes the OLED to emit light.

The first electrode of the first capacitor Cst is connected with the pixel power source line Vdd and the second electrode of the first capacitor Cst is connected with the third node C so that the first capacitor Cst stores the voltage corresponding to the data signal transmitted to the third node C to maintain the voltage for a predetermined time.

The first electrode of the second capacitor Cvth1 is connected with the third node C and the second electrode of the second capacitor Cvth1 is connected with the second node B so that the threshold voltage Vth of the first transistor M1 is stored in the period where the second scan signal sn−1 is supplied to the second scan line Sn−1. The second capacitor Cvth1 stores the threshold voltage Vth of the first transistor M1 in accordance with the switching of the third transistor M3 and the fourth transistor M4.

The first electrode of the third capacitor Cvth2 is connected with the pixel power source line Vdd and the second electrode of the third capacitor Cvth3 is connected with the second node B so that the third capacitor Cvth2 stores the threshold voltage of the first transistor M1 when the third transistor M3 is turned on by the second scan signal sn−1 transmitted through the second scan line Sn−1. The third capacitor Cvth2 is connected to the second capacitor Cvth1 in parallel when the fourth transistor M4 is turned on by the second scan signal sn−1 transmitted through the second scan line Sn−1. Therefore, the second capacitor Cvth1 and the third capacitor Cvth2 are connected with each other in parallel so that the capacity of the capacitor becomes larger. Therefore, it is possible to effectively compensate for the threshold voltage of the first transistor M1.

The third capacitor Cvth2 controls the range of the voltage Vgs between the gate and source of the first transistor M1 in accordance with the capacity of the third capacitor Cvth2. Therefore, the third capacitor Cvth2 controls the swing width of the data signal supplied to the gate terminal of the first transistor M1 in accordance with the capacity of the third capacitor Cvth2.

FIG. 7 is a timing diagram illustrating the operation of the pixel of FIG. 6. Referring to FIG. 7, the pixel is operated by the first and second scan signals sn and sn−1, the data signal, and the first emission control signal En. The first and second scan signals sn and sn−1 and the first emission control signal En are periodical signals.

In a first period T1 where the second scan signal sn−1 is in a low level, the third and fourth transistors M3 and M4 are turned on so that electric current flows through the first transistor M1. The first transistor M1 operates as a diode. The pixel power source is transmitted to the first electrodes of the second and third capacitors Cvth1 and Cvth2.

The voltage corresponding to the difference in voltage between the pixel power source and the threshold voltage of the first transistor M1 is applied to the second node B so that the voltage corresponding to the threshold voltage of the first transistor M1 is stored in the second and third capacitors Cvth1 and Cvth2.

The charge amount of the second node B is obtained by EQUATION 1.
Q=ΣCᵢVᵢ
Q_{N3}(T1)=Cᵥₜₕ₁Vth+Cᵥₜₕ₂Vth [EQUATION 1]

In a second period T2 where the second scan signal sn−1 in a high level is supplied to the second scan line Sn−1 and the first scan signal sn in a low level is supplied to the first scan line Sn, the third and fourth transistors M3 and M4 are turned off and the second transistor M2 is turned on. Therefore, the data signal supplied from the data driver 200 to the data line Dm is supplied to the third node C via the second transistor M2.

Therefore, the data signal and the data signal ΔV data by the compensating voltage stored in the second and third capacitors Cvth1 and Cvth2 are supplied to the gate of the first transistor M1. The charge amount of the second node B and the voltage of the second node B in the second period T2 are obtained by EQUATION 2.

$$Q = \sum {C}_{i} {V}_{i} \\ {Q}_{N3} ( T2 ) = C2 ( {V}_{N3} - {V}_{data} ) + Cvth2 ( {V}_{N3} - VDD ) \\ {Q}_{N3} ( T1 ) - {Q}_{N3} ( T2 ) = 0 \\ {V}_{N3} = \frac{Cvth1}{Cvth1 + Cvth2} Vdata + \frac{Cvth2}{Cvth1 + Cvth2} VDD + Vth \qquad [ EQUATION 2 ]$$

wherein, when Cvth2=0, V_{B}=Vdata−Vth. Also, when Cvth1=Cvth2,

$${V}_{B} = \frac{1}{2} ( Vdata + VDD ) + Vth$$

Therefore, the voltage Vgs between the gate and source of the first transistor M1 can be controlled as represented in EQUATION 3.

$$Vgs = \frac{Cvth1}{Cvth1 + Cvth2} ( Vdata - VDD ) + Vth \qquad [ EQUATION 3 ]$$

As a result, the swing width of the data signal supplied to the data line Dm is obtained by EQUATION 4.

$$Data Swing Range = \frac{Cvth1}{Cvth1 + Cvth2} Δ Vdata \qquad [ EQUATION 4 ]$$

The fifth transistor M5 is turned on in a part of the period where the first scan signal sn in a low level is supplied to the first scan line Sn in accordance with the emission control signal en in a low level supplied to the emission control signal line En. Therefore, the OLED emits light due to the current supplied from the first transistor M1 via the fifth transistor M5.

After the first period T1 where the first scan signal sn in a high level is supplied to the first scan line Sn, the first transistor M1 is turned on by the data signal stored in the first capacitor Cst so that the OLED emits light for one frame.

As described above, even if the threshold voltages Vth of the first transistors M1 in the pixels 110 of the image display unit 100 are different from each other, the threshold voltages Vth of the first transistors M1 are compensated for by the data signals using the second capacitors Cvth1, the third transistors M3, and the fourth transistors M4 so that the currents supplied to the OLEDs are uniform, which makes the brightness of the OLEDs uniform.

The swing width of the data signal is controlled using the capacity of the third capacitor Cvth2. It is therefore possible to prevent the swing width of the data signal from being reduced as the emission effect of the OLED increases.

It is possible to increase the swing width of the data signal because it is possible to control the range of the voltage Vgs between the gate and source of the first transistor M1 by controlling the capacity of the third capacitor Cvth2. As a result, it is possible to increase the swing width of the data signal Vdata which may be reduced as the effect of the OLED increases so that it is possible to easily display gray scales.

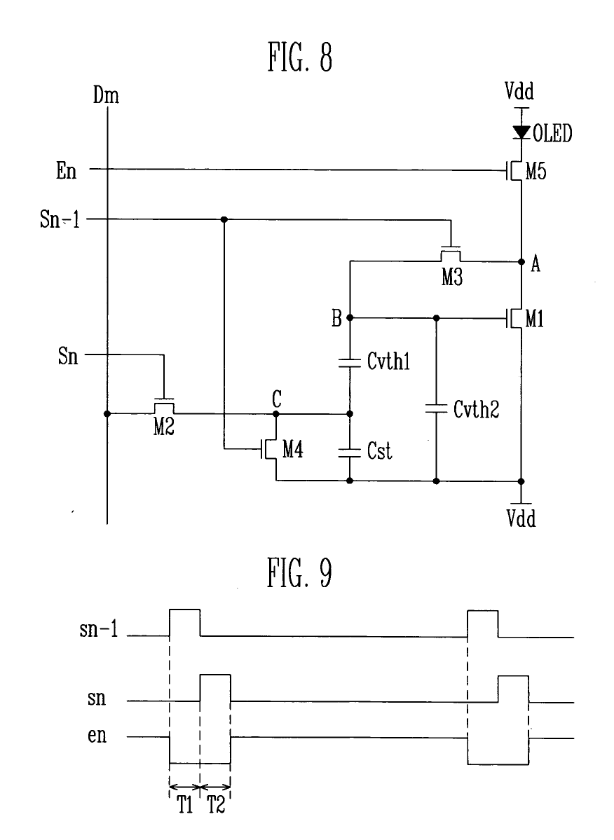

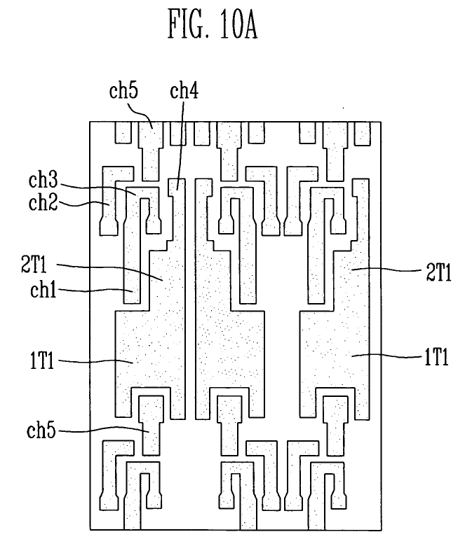

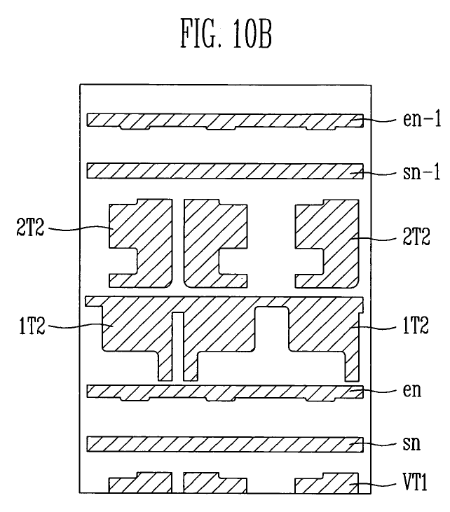

When the pixel of FIG. 6 includes an NMOS transistor, the pixel of FIG. 8 is obtained. The pixel emits light when the signals illustrated in FIG. 9 are input.

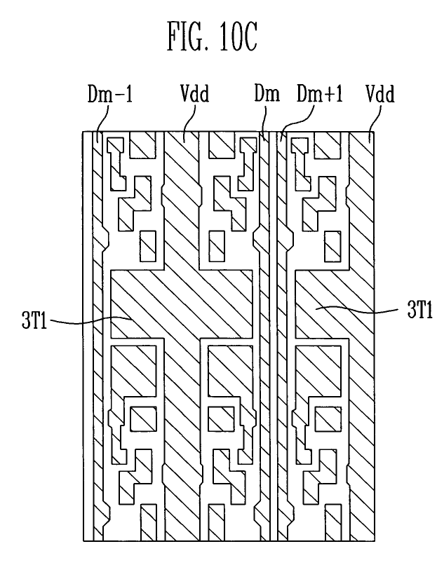

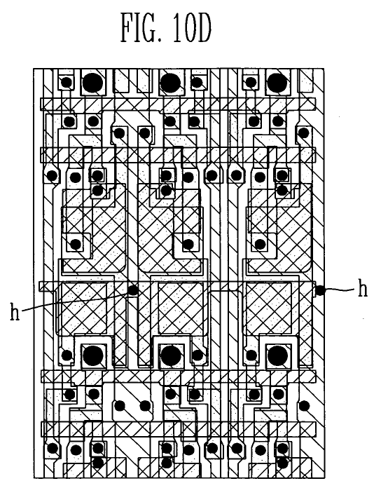

FIG. 10A, FIG. 10B, FIG. 10C, and FIG. 10D are layout diagrams illustrating the layout of the image display unit for which the pixel of FIG. 6 may be used. Referring to FIG. 10, polysilicon is formed on a substrate as illustrated in FIG. 10A to form channel region ch1 of the first transistor, ch2 of the second transistor, ch3 of the third transistor, ch5 of the fifth transistor, the first electrodes 1T1 of the first capacitors Cst, and the first electrodes 2T1 of the second capacitors Cvth1. The channel regions ch1 of the first transistors M1 are connected with the channel regions ch3 of the third transistors M3. The channel regions ch4 of the fourth transistors M4 are connected with the first electrodes 1T1 of the first capacitors Cst. The first electrodes 1T1 of the first capacitors Cst are connected with the first electrodes 2T1 of the second capacitors Vth1. Doped polysilicon or intrinsic polysilicon may be used as the polysilicon.

As illustrated in FIG. 10B, a first metal layer is used to form the emission control lines En on the channel regions ch5 of the fifth transistors M5 in a horizontal direction and the scan lines Sn on the channel region ch3 of the third transistor M3 and the channel region ch4 of the fourth transistor M4 in a horizontal direction. The second electrodes 1T2 of the first capacitors Cst and the second electrodes 2T2 of the second capacitors Cvth1 are formed between the scan lines Sn and the emission control lines En. The second electrodes 2T2 of the second capacitors Cvth1 become the second electrodes 3T2 of the third capacitors Cvth2.

As illustrated in FIG. 10C, a second metal layer is used to form the data lines Dm, the pixel power source lines Vdd, and the first electrodes 3T1 of the third capacitors Cvth2. The two pixels adjacent to each other in a horizontal direction are commonly connected with one pixel power source line Vdd so that the two pixels share one pixel power source line Vdd. Wiring lines are formed so that the channels and the electrodes of the capacitors are electrically connected with each other. The second electrodes 1T2 of the first capacitors Cst and the pixel power source lines Vdd are electrically connected with each other through contact holes h. Insulating layers are formed between the polysilicon layer, the first metal layer, and the second metal layer. FIG. 10D shows the completed image display unit.

Referring to FIG. 10D, the second electrodes 2T2 of the second capacitors Cvth1 and the first electrodes 3T1 of the third capacitors Cvth2 are formed through the first metal layer. Therefore, the second capacitors Cvth1 and the third capacitors Cvth2 are connected with each other in parallel. The pixel power source lines Vdd and the second electrodes 1T2 of the first capacitors Cst are electrically connected with each other so that the power transmitted through the pixel power source lines Vdd are transmitted to the second electrodes 1T2 of the first capacitors Cst. The second electrodes 1T2 of the first capacitors Cst adjacent to each other are connected with each other. Therefore, all of the pixel power source lines Vdd have the same voltage level.

The pixel power source lines Vdd and the second electrodes 1T2 of the first capacitors Cst become power source lines that supply driving power sources to the pixels. The pixel power source lines Vdd and the second electrodes 1T2 of the first capacitors Cst thus form a grid.

When a large amount of current is supplied to one pixel so that a voltage drop is generated in the pixel power source line Vdd directly connected with a pixel 110, the voltage drop is generated in all of the pixel power source lines Vdd because all of the pixel power source lines Vdd are connected with each other by the second electrodes 1T2 of the first capacitors Cst. It is therefore possible to reduce the width of the voltage drop and the drop in the driving voltage of the pixel.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic light emitting display, comprising:
a plurality of pixels;
a plurality of scan lines transmitting scan signals to the plurality of pixels;
a plurality of data lines transmitting data signals to the plurality of pixels; and
a plurality of pixel power source lines transmitting power to the plurality of pixels;
wherein the plurality of pixels comprise a plurality of metal lines that intersect the plurality of pixel power source lines, and
wherein the plurality of metal lines are electrically connected with the plurality of pixel power source lines.

2. The organic light emitting display of claim 1,
wherein the plurality of metal lines are electrically connected with the plurality of pixel power source lines through contact holes.

3. The organic light emitting display of claim 2,
wherein the plurality of pixels comprise capacitors including first electrodes and second electrodes, and
wherein the plurality of metal lines are the second electrodes of the capacitors.

4. The organic light emitting display of claim 3,
wherein the first electrodes of the capacitors are formed in channel regions,
wherein the second electrodes of the capacitors are formed by metal layers, and
wherein the metal layers are electrically connected with gate electrodes.

5. The organic light emitting display of claim 4,
wherein adjacent second electrodes of the capacitors are electrically connected with each other by the plurality of metal lines.

6. The organic light emitting display of claim 5,
wherein the first electrodes of the capacitors comprise doped polysilicon or intrinsic polysilicon.

7. The organic light emitting display of claim 1,
wherein the plurality of pixels further comprise:
a first transistor generating current by the pixel power source in accordance with a first voltage corresponding to a data signal;
a second transistor receiving a scan signal to transmit the data signal to the first transistor;
a capacitor maintaining the first voltage for a predetermined time; and
an organic light emitting diode (OLED) receiving current from the first transistor and emitting light.

8. The organic light emitting display of claim 1, further comprising:
a data driver transmitting the data signals; and
a scan driver transmitting the scan signals.

9. The organic light emitting display of claim 1,
wherein the plurality of metal lines intersect the plurality of data lines; and
wherein the widths of the plurality of metal lines are smaller where the plurality of metal lines intersect the plurality of data lines than the widths of the plurality of metal lines where the plurality of metal lines do not intersect the plurality of data lines.

10. The organic light emitting display of claim 1, further comprising:
a plurality of emission control lines transmitting emission control signals to the plurality of pixels.

11. The organic light emitting display of claim 10,
wherein the plurality of metal lines are electrically connected with the plurality of pixel power source lines through contact holes.

12. The organic light emitting display of claim 10,
wherein the plurality of pixels further comprise:
an OLED;
a first transistor generating current by the pixel power source in accordance with a first voltage corresponding to a data signal;
a second transistor transmitting the data signal to the first transistor in response to a first scan signal;
a first capacitor storing the first voltage for a predetermined time;
a second capacitor storing a threshold voltage of the first transistor for a predetermined time;
a third capacitor storing the threshold voltage of the first transistor for a predetermined time;
a third transistor conducting electric current to the first transistor in accordance with a second scan signal so that the first transistor operates as a diode;
a fourth transistor transmitting power to a first electrode of the second capacitor in accordance with the second scan signal; and
a fifth transistor transmitting current to the OLED in accordance with the emission control signal.

13. The organic light emitting display of claim 12,
wherein second electrodes of the first capacitors of adjacent pixels are electrically connected with each other by the plurality of metal lines.

14. The organic light emitting display of claim 13,
wherein the first electrodes of the first capacitors comprise doped polysilicon or intrinsic polysilicon.

15. The organic light emitting display of claim 13,
wherein the range of the voltage between a gate and a source of the first transistor is controlled in accordance with the capacity of the third capacitor.

16. The organic light emitting display of claim 13,
wherein two adjacent second electrodes of the first capacitors are connected to one pixel power source line.

17. The organic light emitting display of claim 10, further comprising:
a data driver transmitting the data signals; and
a scan driver transmitting the first scan signals, the second scan signals, and the emission control signals.

18. A method of fabricating an organic light emitting display, comprising:
forming channel regions of transistors and first electrodes of capacitors on a substrate, wherein the channel regions of transistors and first electrodes of capacitors comprise polysilicon;
forming a first insulating layer on the channel regions of the transistors and the first electrodes of the capacitors;
forming scan lines and second electrodes of the capacitors on the first insulating layer, wherein adjacent second electrodes of the capacitors are electrically connected with each other and wherein the second electrodes of the capacitors are arranged in a line substantially parallel to the scan lines;
forming a second insulating layer on the scan lines and the second electrodes of the capacitors;
forming contact holes in the second insulating layer so that the contact holes expose the second electrodes of the capacitors; and
forming data lines and pixel power source lines on the second insulating layer, wherein the pixel power source lines are electrically connected with the second electrodes of the capacitors through the contact holes.

19. A method of fabricating an organic light emitting display, comprising:
forming a channel region of a first transistor, a channel region of a second transistor, a channel region of a third transistor, a channel region of a fourth transistor, a channel region of a fifth transistor, a first electrode of a first capacitor, and a first electrode of a second capacitor on a substrate, wherein the channel region of the first transistor, the channel region of the second transistor, the channel region of the third transistor, the channel region of the fourth transistor, the channel region of the fifth transistor, the first electrode of the first capacitor, and the first electrode of the second capacitor comprise polysilicon;
forming a first insulating layer on the channel region of the first transistor, the channel region of the second transistor, the channel region of the third transistor, the channel region of the fourth transistor, the channel region of the fifth transistor, the first electrode of the first capacitor, and the first electrode of the second capacitor;
forming scan lines, emission control lines, a second electrode of the first capacitor, and a second electrode of the second capacitor on the first insulating layer, wherein adjacent second electrodes of the capacitors are electrically connected with each other and wherein the second electrodes of the capacitors are arranged in a line substantially parallel to the scan lines;
forming a second insulating layer on the scan lines, the emission control lines, the second electrode of the first capacitor, and the second electrode of the second capacitor;
forming contact holes in the second insulating layer so that the contact holes expose the second electrodes of the first capacitors; and
forming data lines, pixel power source lines, and the first electrodes of third capacitors on the second insulating layer, wherein the pixel power source lines are electrically connected with the second electrodes of the first capacitors through the contact holes.

20. The method of claim 19,
wherein the second electrodes of the second capacitors are also the second electrodes of the third capacitors.

21. The method of claim 19,
wherein two horizontally adjacent pixels are connected to one emission control line.

22. The method of claim 19,
wherein the second electrodes intersect the data lines; and
wherein the second electrodes are narrower where the second electrodes intersect the data lines.
